(19) United States
(12) Patent Application Publication
(10) Pub. No.: US 2014/0340846 A1
(43) Pub. Date: Nov. 20, 2014

(54) ELECTRONIC APPARATUS

(71) Applicant: FUJITSU LIMITED, Kawasaki-shi (JP)

(72) Inventors: RYO KURITA, Kawasaki (JP); Hideki Maeda, Kawasaki (JP)

(73) Assignee: FUJITSU LIMITED, Kawasaki-shi (JP)

(21) Appl. No.: 14/261,529

(22) Filed: Apr. 25, 2014

(30) Foreign Application Priority Data
May 16, 2013 (JP) 2013-104277

(51) Int. Cl. H05K 7/20

(52) U.S. Cl. CPC H05K 7/20136; H05K 2007/20027
USPC 361/695

(57) ABSTRACT

An electronic apparatus includes: a casing with an air inlet and an air outlet; a plurality of walls that each extend in a direction in which the air inlet is opened, the plurality of walls forming a serpentine ventilation path inside the casing; and an air blower that forms a flow of cooling air, the cooling air flowing from the air inlet to the air outlet through the ventilation path.

### CROSS-REFERENCE TO RELATED APPLICATION

This application is based upon and claims the benefit of priority of the prior Japanese Patent Application No. 2013-104277, filed on May 16, 2013, the entire contents of which are incorporated herein by reference.

### FIELD

The embodiments discussed herein are related to an electronic apparatus.

### BACKGROUND

A known conventional electronic apparatus includes a casing with an air inlet and an air outlet, a plurality of electronic components that form a serpentine ventilation path inside the casing, and an air blower that forms a flow of cooling air, which flows from the air inlet to the air outlet through the ventilation path.

The following is reference document:
[Document 1] Japanese Laid-open Patent Publication No. 02-50496.

### SUMMARY

According to an aspect of the invention, an electronic apparatus includes: a casing with an air inlet and an air outlet; a plurality of walls that each extend in a direction in which the air inlet is opened, the plurality of walls forming a serpentine ventilation path inside the casing; and an air blower that forms a flow of cooling air, the cooling air flowing from the air inlet to the air outlet through the ventilation path.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an information processing apparatus in which an electronic apparatus is installed;

FIG. 2 is a plan cross sectional view of an electronic apparatus according to a first embodiment;

FIG. 3 is a plan cross sectional view illustrating a first variation of the electronic apparatus according to the first embodiment;

FIG. 4 is a plan cross sectional view illustrating a second variation of the electronic apparatus according to the first embodiment;

FIG. 5 is a plan cross sectional view illustrating a third variation of the electronic apparatus according to the first embodiment;

FIG. 6 is a front view illustrating a variation of a computing element;

FIG. 7 is a side view illustrating the variation of the computing element;

FIG. 8 is a plan cross sectional view of an electronic apparatus according to a second embodiment;

FIG. 9 is a cross sectional view cut along line F9-F9 in FIG. 8;

FIG. 10 is a cross sectional view cut along line F10-F10 in FIG. 8;

FIG. 11 is a vertical cross sectional view illustrating a first variation of the electronic apparatus according to the second embodiment;

FIG. 12 is a vertical cross sectional view illustrating a second variation of the electronic apparatus according to the second embodiment;

FIG. 13 is a vertical cross sectional view illustrating a third variation of the electronic apparatus according to the second embodiment;

FIG. 14 is a vertical cross sectional view illustrating a fourth variation of the electronic apparatus according to the second embodiment;

FIG. 15 is a vertical cross sectional view illustrating a fifth variation of the electronic apparatus according to the second embodiment;

FIG. 16 is a vertical cross sectional view illustrating a sixth variation of the electronic apparatus according to the second embodiment; and

FIG. 17 is a vertical cross sectional view illustrating a seventh variation of the electronic apparatus according to the second embodiment.

### DESCRIPTION OF EMBODIMENTS

### First Embodiment

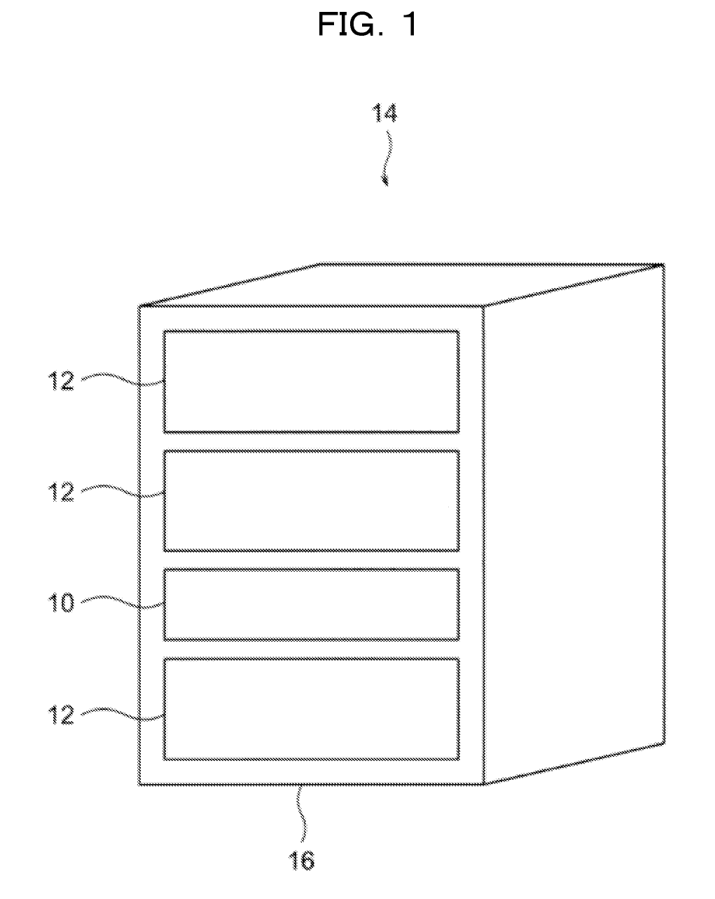

A first embodiment of the present application is described below. As illustrated in FIG. 1, an electronic apparatus 10 according to the first embodiment is installed in a rack 16 of an information processing apparatus 14 together with a plurality of servers 12. For example, the electronic apparatus 10 may be a power supply control apparatus that controls the power supply of the plurality of servers 12.

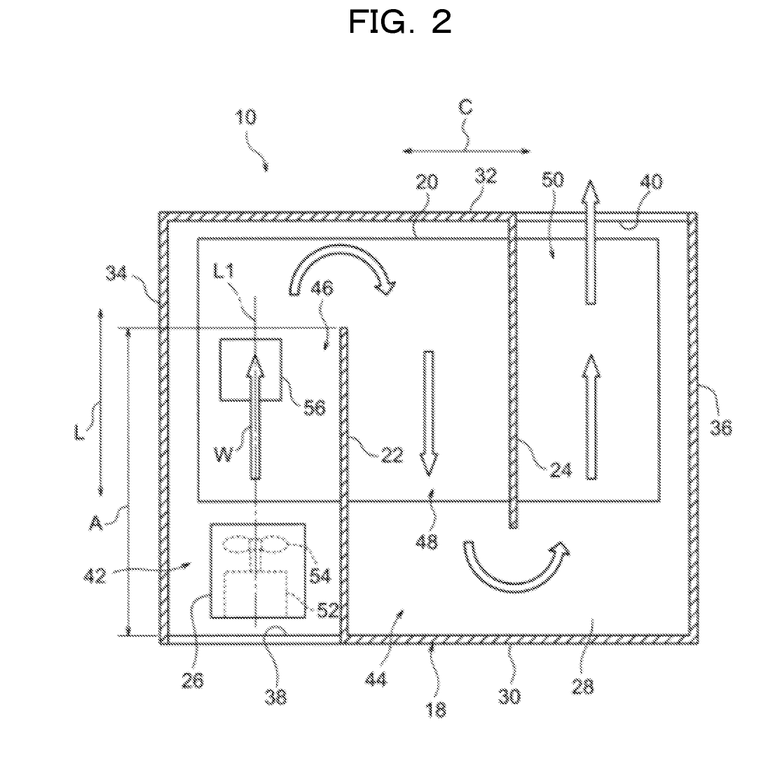

As illustrated in FIG. 2, the electronic apparatus 10 includes a casing 18, a printed board 20, a plurality of wall portions 22 and 24, and an air blower 26.

The casing 18 is formed like a box that includes a top wall portion, which is not illustrated, a bottom wall portion 28, a front wall portion 30, a back wall portion 32, and a left-right pair of side wall portions 34 and 36. The front wall portion 30 and the back wall portion 32 extend along a width direction of the casing 18, which is a direction of an arrow C, and face each other in a depth direction of the casing 18, which is a direction of an arrow L. The left-right pair of side wall portions 34 and 36 extends along the depth direction of the casing 18 and faces each other in the width direction of the casing 18.

The front wall portion 30 and the back wall portion 32, which are an example of a pair of vertical wall portions, are provided with an air inlet 38 and an air outlet 40, respectively. The air inlet 38 and the air outlet 40 are shifted in the width direction of the casing 18. That is, the air inlet 38 is formed on the side of the front wall portion 30 at an end in the width direction while the air outlet 40 is formed on the side of the back wall portion 32 at the other end in the width direction. The air inlet 38 and the air outlet 40 are opened in the depth direction of the casing 18.

The printed board 20 is accommodated inside the casing 18. The printed board 20 extends in the width direction and the depth direction of the casing 18 and is arranged while a height direction of the casing 18 serves as a plate thickness direction of the printed board 20. A gap 42 is provided between the printed board 20 and the front wall portion 30 in the depth direction of the casing 18.

Each of the wall portions 22 and 24 extends along the depth direction of the casing 18, which is a direction in which the air inlet 38 is opened. The wall portions 22 and 24 are arranged apart in the width direction of the casing 18. One of the wall portions, 22, is coupled to the front wall portion 30 and separated from the back wall portion 32 in the depth direction of the casing 18. The other wall portion 24 is coupled to the back wall portion 32 and separated from the front wall portion 30 in the depth direction of the casing 18. While the wall portions 22 and 24 are arranged so as to be shifted in this manner, a serpentine ventilation path 44 is formed inside the casing 18.

That is, a region between the wall portion 22 and one of the side wall portions, 34, is referred to as an upstream region 46 of the ventilation path 44, and a region between the wall portion 22 and the other wall portion 24 is referred to as a midstream region 48 of the ventilation path 44. Further, a region between the other wall portion 24 and the other side wall portion 36 is referred to as a downstream region 50 of the ventilation path 44. The upstream region 46 is coupled to the air inlet 38 and the downstream region 50 is coupled to the air outlet 40. Further, an opening between the wall portion 22 and the back wall portion 32 allows the upstream region 46 and the midstream region 48 to communicate, and an opening between the other wall portion 24 and the front wall portion 30 allows the midstream region 48 and the downstream region 50 to communicate. Each of the upstream region 46, the midstream region 48, and the downstream region 50 extends along the depth direction of the casing 18.

The air blower 26 is arranged so as to face the air inlet 38 in the depth direction of the casing 18. The air blower 26 is arranged in the gap 42 between the printed board 20 and the front wall portion 30 and positioned near the air inlet 38. The air blower 26 includes a motor 52 and a fan 54 that rotates because of the motor 52. When the motor 52 operates and the fan 54 rotates, a flow of cooling air W, which flows from the air inlet 38 to the air outlet 40 through the ventilation path 44, is formed. In the first embodiment, one air blower is used, which is the air blower 26.

On the above-described printed board 20, a computing element 56, such as a central processing unit (CPU) or a micro processing unit (MPU), is mounted as an example of a target object to be cooled. The computing element 56 is arranged in the upstream region 46 of the ventilation path 44. Further, the computing element 56 overlaps the wall portion 22 in a direction of the flow of the cooling air W, which is the direction of the arrow L. That is, the computing element 56 is arranged so as to be included in a range A in a depth direction of the wall portion 22. Further, the computing element 56 is arranged on an extension line L1 of a center axis of the fan 54 provided to the air blower 26.

Advantages of the first embodiment are described below. As described in detail above, in the electronic apparatus 10 according to the first embodiment, each of the wall portions 22 and 24 forming the serpentine the ventilation path 44 inside the casing 18 extends along the depth direction of the casing 18, which is the direction of the arrow L and the direction in which the air inlet 38 is opened. Thus, the cooling air W taken from the air inlet 38 flows along the wall portion 22 on the upstream side of the ventilation path 44 and as a result, reduction in the speed of the cooling air W may be suppressed. Accordingly, the performance in cooling the computing element 56 may be enhanced.

In addition, the computing element 56 overlaps the wall portion 22 in the direction of the flow of the cooling air W (the direction of the arrow L). Thus, the cooling air W that flows along the wall portion 22 may be supplied to the computing element 56, and the performance in cooling the computing element 56 may be further enhanced.

Moreover, the air blower 26 is arranged so as to face the air inlet 38 in the direction in which the air inlet 38 is opened. Thus, air resistance between the air blower 26 and the air inlet 38 may be decreased. In addition, the computing element 56 is arranged on the extension line L1 of the center axis of the fan 54 provided to the air blower 26. Accordingly, the cooling air W may be supplied smoothly to the computing element 56 and this also may further enhance the performance in cooling the computing element 56.

In addition, the number of air blowers that are used is one, that is, the air blower 26. Thus, the performance in cooling the computing element 56 may be enhanced while suppressing noise and power consumption as well as increase in costs.

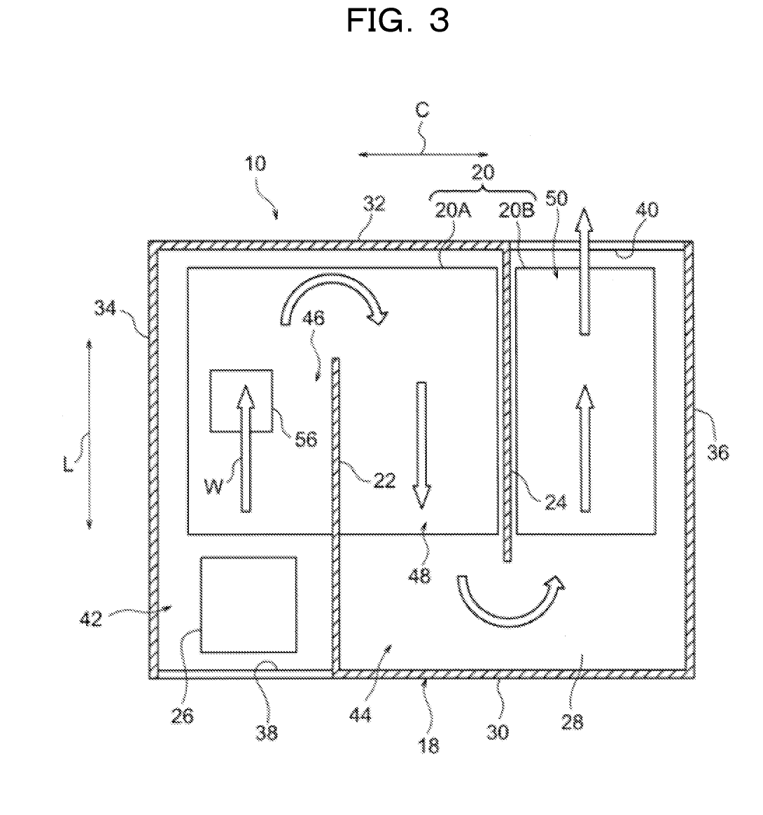

Variations of the first embodiment are described below. As illustrated in FIG. 3, in the above-described first embodiment, the printed board 20 may be divided into a plurality of printed boards 20A and 20B. That is, the plurality of printed boards 20A and 20B may be accommodated inside the casing 18.

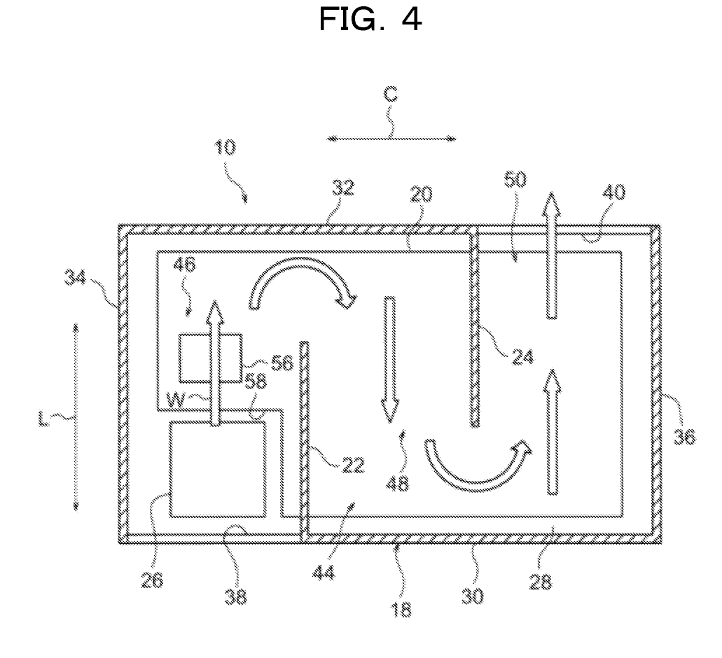

Also, as illustrated in FIG. 4, a cut portion 58 may be formed at a corner of the printed board 20, which is located on the side of the front wall portion 30 and on the side of the side wall portion 34, and the air blower 26 may be arranged in the cut portion 58. According to this configuration, the casing 18 may be made smaller in the depth direction (the direction of the arrow L).

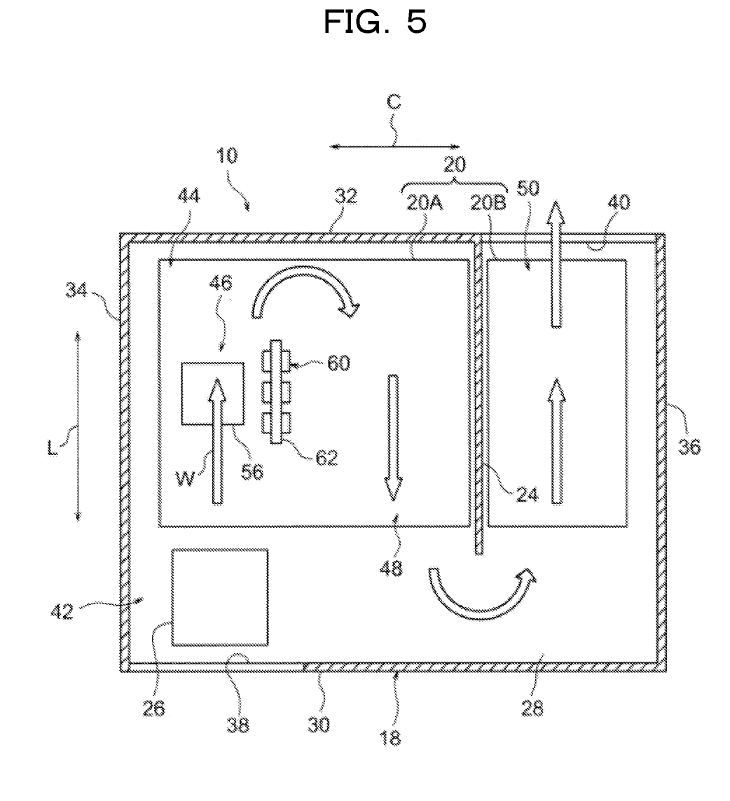

Further, as illustrated in FIG. 5, a memory module 60, such as a dual inline memory module (DIMM), may be mounted on the printed board 20 as an example of an electronic component. A board 62 of the memory module 60 may form a wall portion in the upstream region 46. In this case, the board 62 that has a function of the wall portion that guides the cooling air W may be separated from the front wall portion 30 and the back wall portion 32 in the depth direction of the casing 18 (the direction of the arrow L).

Even when the board 62 that guides the cooling air W is separated from the front wall portion 30, the board 62 extends along the depth direction of the casing 18, which is the direction in which the air inlet 38 is opened, and thus, the cooling air W taken from the air inlet 38 may be caused to flow along the board 62. Accordingly, the board 62 may be arranged apart from the front wall portion 30 and the memory module 60 may be arranged more freely.

In the variation illustrated in FIG. 5, the computing element 56, the memory module 60, and the printed board 20B, which are arranged in order from the upstream side to the downstream side in the direction of the flow of the cooling air W, may be set so that demands for the cooling may decrease in this order.

Further, in the variation illustrated in FIG. 5, a voltage converter, such as a direct current to direct current (DC-to-DC) converter, may be mounted on the printed board 20 instead of the memory module 60 as an example of the electronic component. A board of the voltage converter may form the wall portion in the upstream region 46. A wall portion in the downstream region 50 may also be formed by the board of the electronic component.

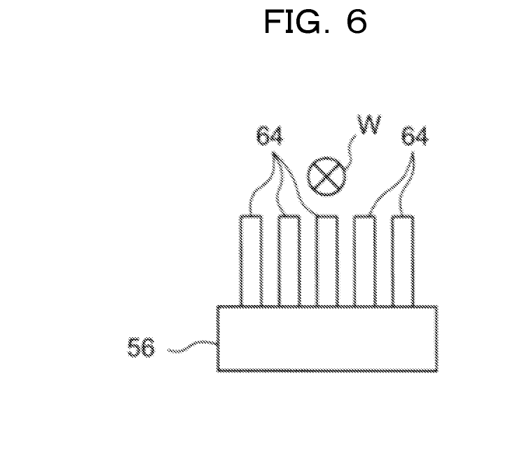

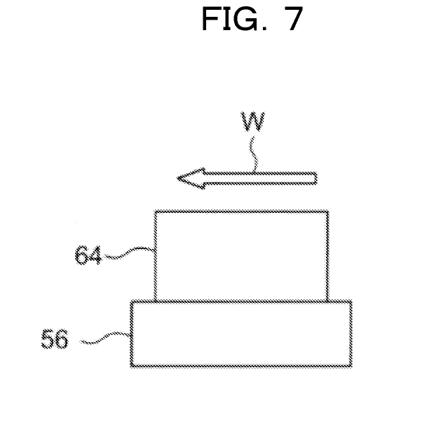

As illustrated in FIGS. 6 and 7, the computing element 56 may be provided with a plurality of cooling fins 64. Since this configuration enables the computing element 56 to be cooled through the cooling fins 64, the performance in cooling the computing element 56 may be enhanced. It is preferable that the plurality of cooling fins 64 extend in the direction of the flow of the cooling air W. This configuration may reduce the possibility of the plurality of cooling fins 64 hindering the flow of the cooling air W.

Further, in the above-described first embodiment, the air blower 26 illustrated in FIG. 2 may be arranged near the air outlet 40 or may be arranged in a middle portion (the midstream region 48) of the ventilation path 44.

In addition, for example, the air inlet 38 may be opened in the width direction of the casing 18 (the direction of the arrow C). When the air inlet 38 is opened in the width direction of the casing 18, each of the wall portions 22 and 24 may extend along the width direction of the casing 18 and may be arranged apart in the depth direction (the direction of the arrow L) of the casing 18.

Moreover, the above-described variations of the first embodiment may be implemented by being combined as appropriate.

### Second Embodiment

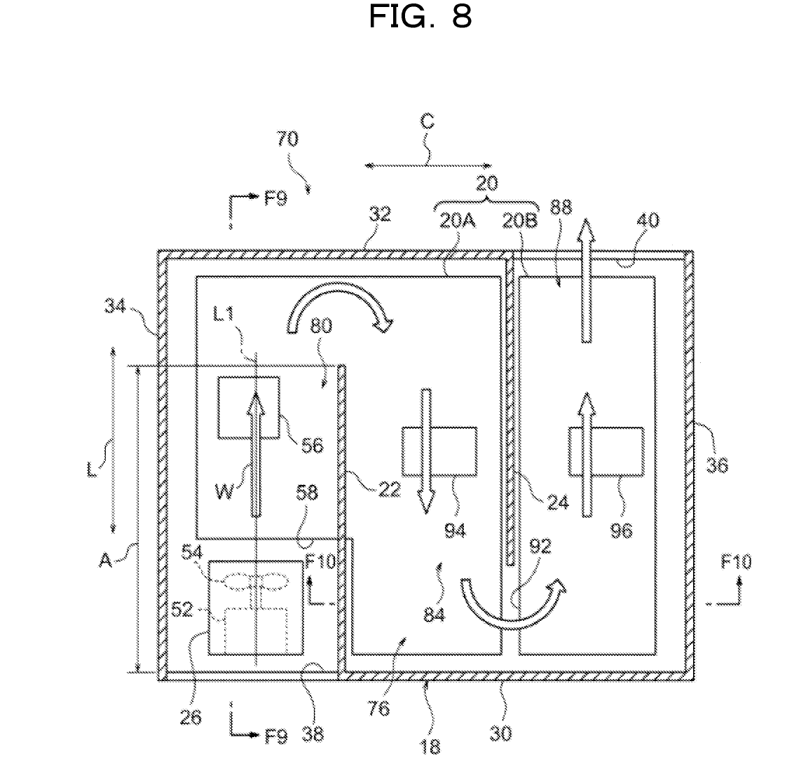

A second embodiment of the present application is described below. An electronic apparatus 70 according to the second embodiment, which is illustrated in FIGS. 8 to 10, is configured as described below by making changes to the electronic apparatus 10 according to the above-described first embodiment (see FIGS. 1 to 5). In the second embodiment, reference numerals and letters the same as the reference numerals and letters that are used in the above-described first embodiment are given to elements similar to the elements in the first embodiment, and the explanations of such elements are omitted.

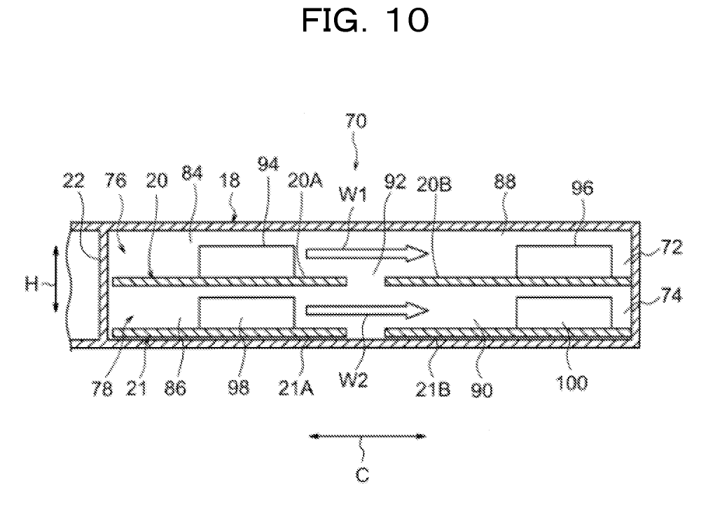

As illustrated in FIG. 10, in the electronic apparatus 70 according to the second embodiment, a plurality of printed boards 20 and 21 arranged in two levels, that is, an upper level and a lower level, are accommodated inside a casing 18. The printed board 20 in the upper level is divided into a plurality of printed boards 20A and 20B. The printed board 21 in the lower level has a shape similar to the shape of the printed board 20 in the upper level and is divided into a plurality of printed boards 21A and 21B.

The printed boards 20A and 21A are arranged so as to face each other in a height direction of the casing 18, which is a direction of an arrow H, and the printed boards 20B and 21B are arranged so as to face each other in the height direction of the casing 18. Further, the printed boards 20A and 21A are arranged so as to be parallel to the printed boards 20B and 21B in a width direction of the casing 18, which is a direction of an arrow C.

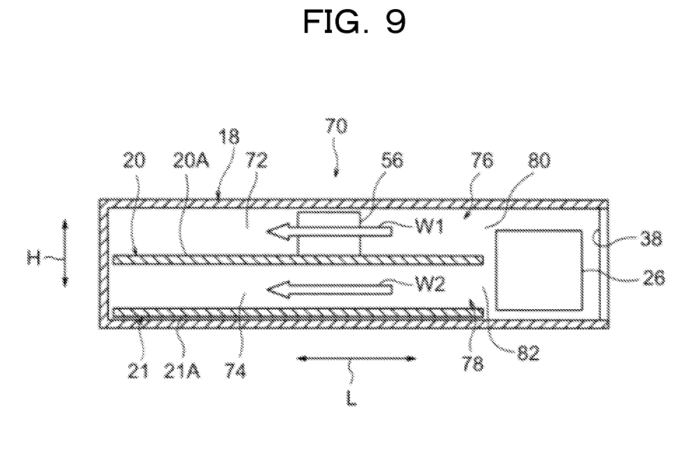

As illustrated in FIG. 10, the printed board 20 in the upper level is arranged in a central portion in the height direction of the casing 18. The inside of the casing 18 is partitioned into an upper space 72 and a lower space 74 by the printed board 20, which is an example of a partition wall. Ventilation paths 76 and 78 are formed in the spaces 72 and 74, respectively; along a plurality of wall portions 22 and 24 (see FIG. 8). As illustrated in FIG. 8, the ventilation path 76 includes an upstream region 80, a midstream region 84, and a downstream region 88. Similarly, the ventilation path 78 includes an upstream region 82, a midstream region 86, and a downstream region 90 (see FIGS. 9 and 10).

As illustrated in FIG. 8, an edge portion of the printed board 20 on the side of a front wall portion 30 is positioned near the front wall portion 30. One of the wall portions, 22, is arranged in a central portion of the printed board 20A in the width direction while the other wall portion 24 is arranged between the printed board 20A and the printed board 20B. A gap 92 is provided between the other wall portion 24 and the front wall portion 30 and between the printed board 20A and the printed board 20B. As illustrated in FIG. 10, the gap 92, which is an example of a communication opening, allows middle portions between the upstream side and the downstream side of the upper ventilation path 76 and the lower ventilation path 78 to communicate, which are a coupling portion of the midstream region 84 and the downstream region 88 on the upper side and a coupling portion of the midstream region 86 and the downstream region 90 on the lower side.

As illustrated in FIG. 8, an air blower 26 is arranged in a cut portion 58 provided to the printed board 20. When a motor 52 of the air blower 26 operates and a fan 54 rotates a flow of cooling air is formed, which flows from an air inlet 38 to an air outlet 40 through each of the ventilation paths 76 and 78 (see FIGS. 9 and 10). That is, as illustrated in FIGS. 9 and 10, cooling air W1 flows through the ventilation path 76 in the upper level and cooling air W2 flows through the ventilation path 78 in the lower level. As further illustrated in FIG. 8, the number of air blowers used in the second embodiment is also one, that is, the air blower 26.

A computing element 56 is arranged in the upstream region 80 of the ventilation path 76 in the upper level. Similar to a case in the first embodiment, the computing element 56 overlaps the wall portion 22 in a direction of the flow of the cooling air W1, which is a direction of an arrow L. Further, the computing element 56 is arranged on an extension line L1 of a center axis of the fan 54 provided to the air blower 26. As illustrated in FIG. 9, a target object to be cooled, such as the computing element, is not arranged in the upstream region 82 of the ventilation path 78 in the lower level.

In addition, as illustrated in FIG. 10, a high heat generating component 94 and a low heat generating component 96, which are examples of a plurality of heating elements, are mounted on the printed boards 20A and 20B in the upper level, respectively. The high heat generating component 94 is arranged in the midstream region 84 of the ventilation path 76 in the upper level, and the low heat generating component 96 is arranged in the downstream region 88 of the ventilation path 76 in the upper level. When the high heat generating component 94 is an example of a first heating element, the low heat generating component 96 is an example of a second heating element. The high heat generating component 94 generates heat with a temperature that is higher than the temperature of heat generated by the low heat generating component 96 arranged on the downstream side of the high heat generating component 94 in the ventilation path 76.

Meanwhile, a low heat generating component 98 and a high heat generating component 100, which are examples of the plurality of heating elements, are mounted on the printed boards 21A and 21B in the lower level, respectively. The low heat generating component 98 is arranged in the midstream region 86 of the ventilation path 78 in the lower level, and the high heat generating component 100 is arranged in the downstream region 90 of the ventilation path 78 in the lower level. When the low heat generating component 98 is an example of the first heating element, the high heat generating component 100 is an example of the second heating element. The low heat generating component 98 generates heat with a temperature that is lower than the temperature of heat generated by the high heat generating component 100 arranged on the downstream side of the low heat generating component 98 in the ventilation path 78.

Advantages unique to the second embodiment are described below. As described in detail above, in the electronic apparatus 70 according to the second embodiment (see FIGS. 8 to 10), the inside of the casing 18 is partitioned into the space 72 in the upper level and the space 74 in the lower level by the printed board 20. Then, the ventilation paths 76 and 78 are formed in the spaces 72 and 74, respectively, along the wall portions 22 and 24. Thus, the computing element 56, the high heat generating component 94, and the low heat generating component 96, which are arranged in the ventilation path 76 in the upper level, and the low heat generating component 98 and the high heat generating component 100, which are arranged in the ventilation path 78 in the lower level, may both be cooled.

As illustrated in FIG. 10, in the ventilation path 76 in the upper level, the high heat generating component 94 is arranged on the upstream side, compared to the low heat generating component 96. Thus, the cooling air W1 may be supplied to the high heat generating component 94 earlier than the low heat generating component 96 and as a result, the high heat generating component 94 may be cooled with high efficiency. In addition, the cooling air W1 that is heated by flowing over the high heat generating component 94 is supplied to the low heat generating component 96, which is less desired to be cooled than the high heat generating component 94. Accordingly, each of the high heat generating component 94 on the upstream side and the low heat generating component 96 on the downstream side may be supplied with the cooling air that has a temperature suitable for the heating state and as a result, both the high heat generating component 94 and the low heat generating component 96 may be cooled.

Further, in the ventilation path 78 in the lower level, the low heat generating component 98 is arranged on the upstream side, compared to the high heat generating component 100. Thus, the cooling air W2 having a temperature that remains low after flowing over the low heat generating component 98 may be supplied to the high heat generating component 100. As a result, both the low heat generating component 98 and the high heat generating component 100 may be cooled.

Variations of the second embodiment are described below. In the above-described second embodiment, the quantity of the flow of the cooling air supplied from the air blower 26 to the ventilation path 76 in the upper level may differ from the quantity of the flow of the cooling air supplied from the air blower 26 to the ventilation path 78 in the lower level.

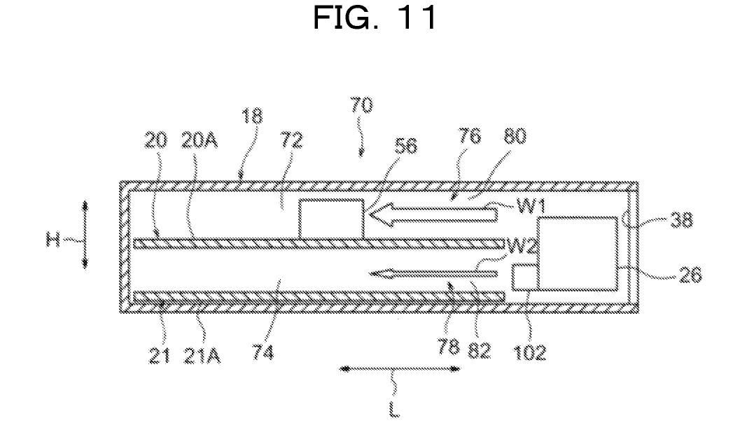

For example, in a variation illustrated in FIG. 11, a connector 102 of the air blower 26 is arranged in a beginning portion of the ventilation path 78 in the lower level. Since the connector 102 hinders the flow of the cooling air W2 into the ventilation path 78 in the lower level, the quantity of the flow of the cooling air W1 supplied to the ventilation path 76 in the upper level is larger than the quantity of the flow of the cooling air W2 supplied to the ventilation path 78 in the lower level. According to this configuration, more cooling air may be supplied to the ventilation path 76 in the upper level in which the computing element 56 is arranged and thus, the performance in cooling the computing element 56 may be enhanced.

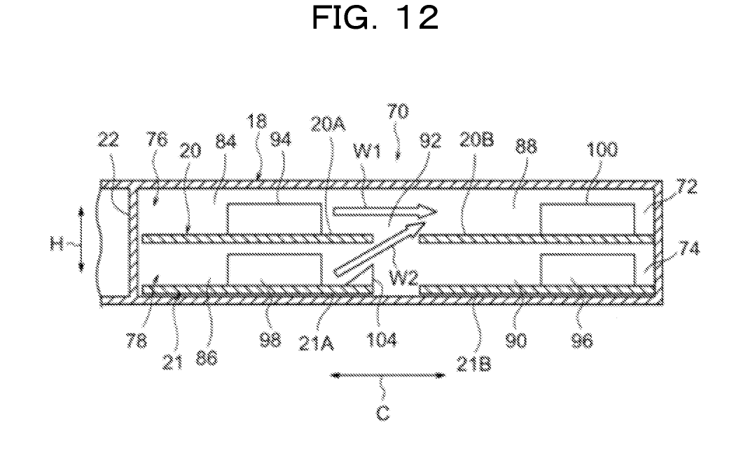

Further, as illustrated in FIG. 12, in the above-described second embodiment, the high heat generating component 100 may be arranged in the downstream region 88 of the ventilation path 76 in the upper level, and the low heat generating component 96 may be arranged in the downstream region 90 of the ventilation path 78 in the lower level.

Moreover, in this case, a wind direction control member 104 provided to the printed board 21A in the lower level may cause the cooling air W2 to flow from the upstream side (the midstream region 86) of the ventilation path 78 in the lower level to the downstream side (the downstream region 88) of the ventilation path 76 in the upper level through the gap 92. Since the wind direction control member 104, which is an example of a wind direction control unit, has no influence on the flow of the cooling air W1 in the ventilation path 76 in the upper level, the cooling air W1 flows from the upstream side to the downstream side, that is, from the midstream region 84 to the downstream region 88 in the ventilation path 76 in the upper level.

This configuration may enable the cooling air W1 and W2 to be concentrated in the downstream region 88 of the ventilation path 76 in the upper level, in which the high heat generating component 100 is arranged, and thus, the performance in cooling the high heat generating component 100 may be enhanced.

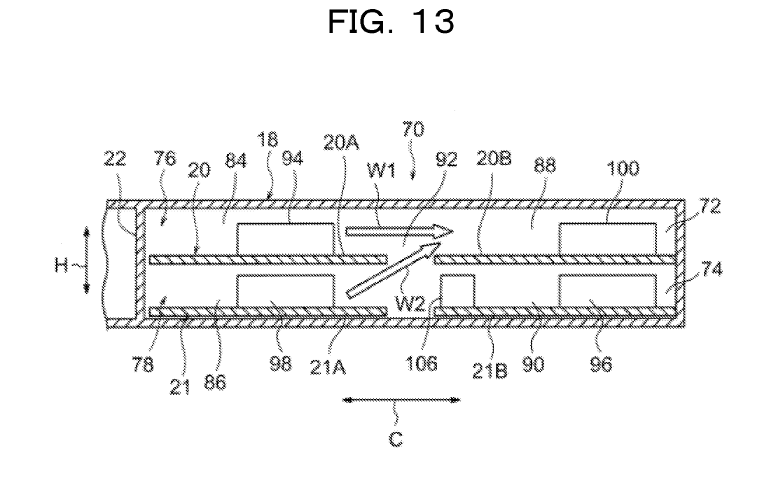

As illustrated in FIG. 13, because of a mounted component 106 on the printed board 21B, the cooling air W2 may flow from the upstream side (the midstream region 86) of the ventilation path 78 in the lower level to the downstream side (the downstream region 88) of the ventilation path 76 in the upper level though the gap 92. Since the mounted component 106, which is an example of the wind direction control unit, has no influence on the flow of the cooling air W1 in the ventilation path 76 in the upper level, the cooling air W1 flows from the upstream side to the downstream side, that is, from the midstream region 84 to the downstream region 88 in the ventilation path 76 in the upper level.

This configuration may also enable the cooling air W1 and W2 to be concentrated in the downstream region 88 of the ventilation path 76 in the upper level, in which the high heat generating component 100 is arranged, and thus, the performance in cooling the high heat generating component 100 may be enhanced.

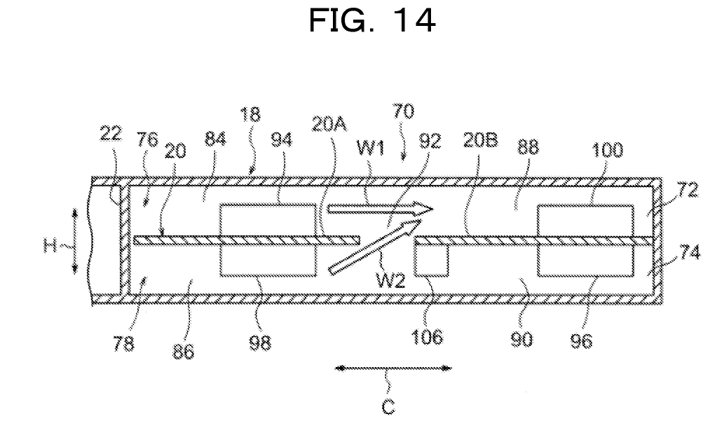

As illustrated in FIG. 14, the above-described printed board 21 in the lower level may be omitted. Further, the high heat generating components 94 and 100 arranged in the ventilation path 76 in the upper level may be mounted on one of mount surfaces, which is a top surface, of the printed board 20, and the low heat generating components 98 and 96 arranged in the ventilation path 78 in the lower level may be mounted on the other mount surface, which is a back surface, of the printed board 20.

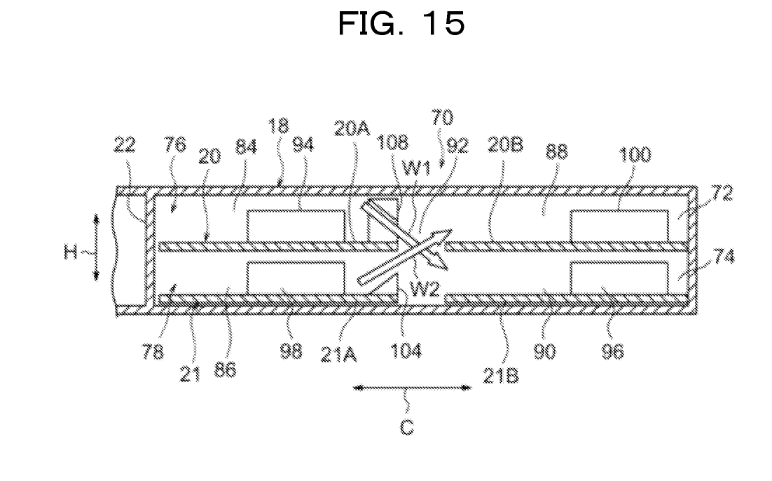

As illustrated in FIG. 15, in the above-described variation illustrated in FIG. 12, a wind direction control member 108, which is an example of the wind direction control unit, may be provided to the printed board 20A in the upper level. Because of the wind direction control member 108, the cooling air W1 may flow from the upstream side (the midstream region 84) of the ventilation path 76 in the upper level to the downstream side (the downstream region 90) of the ventilation path 78 in the lower level through the gap 92. In this case, the printed board 20 may be provided with a communication opening through which the cooling air W1 that flows from the upstream side of the ventilation path 76 in the upper level to the downstream side of the ventilation path 78 in the lower level passes, and a communication opening through which the cooling air W2 that flows from the upstream side of the ventilation path 78 in the lower level to the downstream side of the ventilation path 76 in the upper level passes, at separate positions. In the variations illustrated in FIGS. 12 to 15, the ventilation path 76 in the upper level is an example of one ventilation path and the ventilation path 78 in the lower level is an example of another ventilation path.

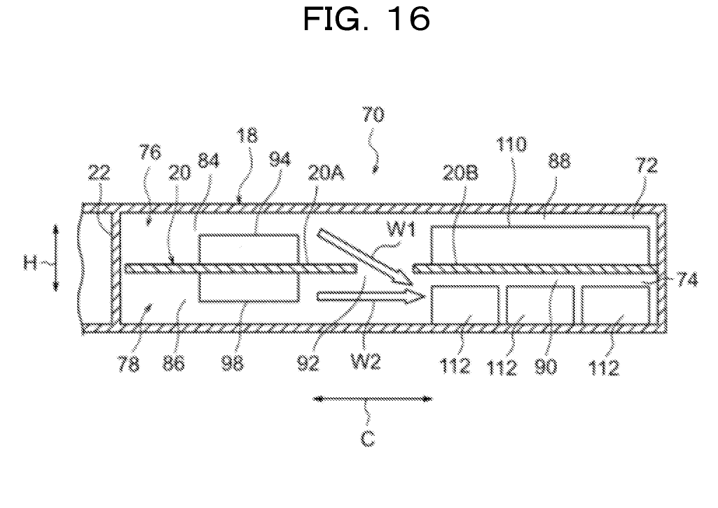

As illustrated in FIG. 16, an expansion unit 110 may be arranged in the downstream region 88 of the ventilation path 76 in the upper level, and a plurality of power supply units 112 may be arranged in the downstream region 90 of the ventilation path 78 in the lower level. The expansion unit 110 and the plurality of power supply units 112 are examples of the heating element. The plurality of power supply units 112 generate heat with a temperature that is higher than the temperature of heat generated by the expansion unit 110.

In the variation illustrated in FIG. 16, the expansion unit 110 is arranged so as to occupy the whole of the downstream region 88 of the ventilation path 76 in the upper level. Thus, the expansion unit 110 hinders the flow of the cooling air W1 from the upstream side to the downstream side in the ventilation path 76 in the upper level. As a result, the cooling air W1 flows from the upstream side (the midstream region 84) of the ventilation path 76 in the upper level to the downstream side (the downstream region 90) of the ventilation path 78 in the lower level through the gap 92. Since the expansion unit 110, which is an example of the wind direction control unit, has no influence on the flow of the cooling air W2 in the ventilation path 78 in the lower level, the cooling air W2 flows from the upstream side to the downstream side, that is, from the midstream region 86 to the downstream region 90 in the ventilation path 78 in the lower level.

This configuration may enable the cooling air W1 and W2 to be concentrated in the downstream region 90 of the ventilation path 78 in the lower level, in which the plurality of power supply units 112 are arranged, and thus, the performance in cooling the plurality of power supply units 112 may be enhanced.

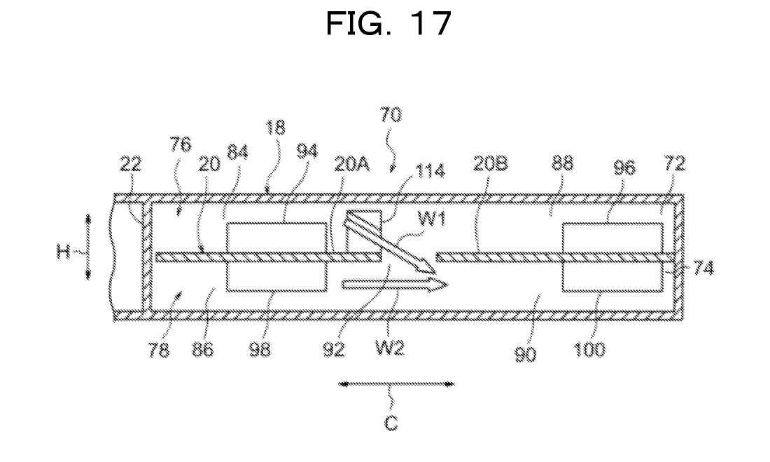

As illustrated in FIG. 17, in the variation illustrated in FIG. 16, the low heat generating component 96 may be arranged instead of the expansion unit 110, and the high heat generating component 100 may be arranged instead of the power supply units 112. The cooling air W1 and W2 may be concentrated in the downstream region 90 of the ventilation path 78 in the lower level by mounting a wind direction control member 114 on the printed board 20A. Further, the high heat generating component 94 and the low heat generating component 96 may be mounted on one of the mount surfaces (the top surface) of the printed board 20, and the low heat generating component 98 and the high heat generating component 100 may be mounted on the other mount surface (the back surface) of the printed board 20. In the variations illustrated in FIGS. 16 and 17, the ventilation path 78 in the lower level is an example of one ventilation path and the ventilation path 76 in the upper level of an example of another ventilation path.

Further, in the above-described second embodiment, a partition wall may be provided instead of the printed board 20. In addition, the partition wall may be provided with a communication opening that allows the middle portions between the upstream side and the downstream side of the ventilation path 76 in the upper level and the ventilation path 78 in the lower level to communicate, which are described above.

The inside of the casing 18 may be provided with a plurality of partition walls that face in the height direction of the casing 18 and may be partitioned into a plurality of spaces, such as three or more spaces. Further, the inside of the casing 18 may be provided with three or more wall portions, and the ventilation paths 76 and 78 may be divided into four or more regions.

The above-described variations of the second embodiment may be implemented by being combined as appropriate. Also, the above-described variations of the second embodiment may be implemented by being combined with the first embodiment and the variations thereof as appropriate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic apparatus comprising:
a casing with an air inlet and an air outlet;
a plurality of walls that each extend in a direction in which the air inlet is opened, the plurality of walls forming a serpentine ventilation path inside the casing; and
an air blower that forms a flow of cooling air, the cooling air flowing from the air inlet to the air outlet through the ventilation path.

2. The electronic apparatus according to claim 1, wherein
a target object to be cooled is arranged in the ventilation path.

3. The electronic apparatus according to claim 2, wherein
the air blower is arranged so as to face the air inlet in the direction in which the air inlet is opened, and
the target object to be cooled is arranged in an extension line of a center axis of a fan provided to the air blower.

4. The electronic apparatus according to claim 1, wherein
a printed board is accommodated inside the casing,
the casing includes a pair of vertical walls that face each other in the direction in which the air inlet is opened,
at least one of the plurality of walls is a board of an electronic component mounted on the printed board, and
the board of the electronic component is separated from the pair of vertical walls in the direction in which the air inlet is opened.

5. The electronic apparatus according to claim 4, wherein
the electronic component is one of a memory module and a voltage converter.

6. The electronic apparatus according to claim 1, wherein
a printed board is accommodated inside the casing,
the printed board includes a cut portion, and the air blower is arranged in the cut portion.

7. The electronic apparatus according to claim 1, wherein
a target object to be cooled is arranged in the ventilation path, and
a cooling fin that extends in a direction of the flow of the cooling air is provided to the target object to be cooled.

8. The electronic apparatus according to claim 1, wherein
a first object generating heat is arranged at an upper stream side of the ventilation path and a second object generating heat is arranged at an lower stream side of the ventilation path, and
the first object generates heat with a temperature that is higher than a temperature of heat generated by the second object.

9. The electronic apparatus according to claim 1, wherein
a first object generating heat is arranged at an upper stream side of the ventilation path and a second object generating heat is arranged at an lower stream side of the ventilation path, and
the first object generates heat with a temperature that is lower than a temperature of heat generated by the second object.

10. The electronic apparatus according to claim 1, wherein
an inside of the casing is partitioned into a plurality of spaces by a partition wall accommodated inside the casing, and
the ventilation path is formed in each of the plurality of spaces as a plurality of ventilation paths.

11. The electronic apparatus according to claim 10, wherein
the partition wall includes a communication opening that allows middle portions between an upstream side and a downstream side of the plurality of ventilation paths to communicate, and
a wind direction control unit is provided inside the casing, the wind direction control unit causing cooling air to flow to the downstream side of one ventilation path included in the plurality of ventilation paths from the upstream side of another ventilation path included in the plurality of ventilation paths through the communication opening.

12. The electronic apparatus according to claim 11, wherein
a first object generating heat is arranged at the downstream side of the one ventilation path and a second object generating heat is arranged at the downstream side of the another ventilation path, and
the first object generates heat with a temperature that is higher than a temperature of heat generated by the second object.

13. The electronic apparatus according to claim 12, wherein
a third object generating heat is arranged at the upstream side of the one of the plurality of ventilation paths, generates heat with a temperature that is higher than a temperature of heat generated by the first object, and
the wind direction control unit causes cooling air to flow from the upstream side to the downstream side of the one ventilation path.

14. The electronic apparatus according to claim 12, wherein
a third object generating heat is arranged at the upstream side of the one of the plurality of ventilation paths, generates heat with a temperature that is higher than a temperature of heat generated by the first object, and
the wind direction control unit causes cooling air to flow from the upstream side of the one ventilation path to the downstream side of the another ventilation path through the communication opening.

15. The electronic apparatus according to claim 12, wherein
a third object generating heat is arranged at the upstream side of the one of the plurality of ventilation paths, generates heat with a temperature that is lower than a temperature of heat generated by the first object, and
the wind direction control unit causes cooling air to flow from the upstream side to the downstream side of the one ventilation path.

16. The electronic apparatus according to claim 10, wherein
the partition wall is a printed board, and
a first object generating heat is arranged in the one ventilation path on a first surface of the printed board, and
a second object generating heat is arranged in the another ventilation path on a second surface of the printed board.
